(19) United States
(12) Patent Application Publication
(10) Pub. No.: US 2003/0174018 A1
(43) Pub. Date: Sep. 18, 2003

(54) Circuit comprising amplifiers connected in parallel, and a method of reducing the difference in amplitude between output signals from amplifiers thereof

(76) Inventors: Stephen Edward Cooper, Swindon (GB); Robert Jones, Stonehouse (GB)

Correspondence Address: Docket Administrator (Room 3J-219), Lucent Technologies Inc., 101 Crawfords Corner Road, Holmdel, NJ, 07733-3030, US

(21) Appl. No.: 10/379,019

(22) Filed: Mar. 4, 2003

(30) Foreign Application Priority Data
Mar. 13, 2002 (EP) 02251799.9

(51) Int. Cl. H03F 3/68

(52) U.S. Cl. 330/124 R

(57) ABSTRACT

A circuit is provided comprising at least two amplifiers (20,22,120,122,220,222,320,322) electrically coupled in parallel. The circuit includes a controller (38,138,238,338) operative to reduce the difference in amplitude between output signals from the amplifiers. The controller (38,138,238,338) is operative to determine or receive an indicator of the difference in amplitude between the output signal (A) of a first amplifier (20,120,220,320) and the output signal (B) of a second amplifier (22,122,222,322), and to adjust the gain of at least one of the first and second amplifiers dependent upon the indicator.

### CROSS REFERECE TO RELATED APPLICATION

This application claims priority of European Application No. 02251799.9 filed on Mar. 13, 2002.

1. Field of the Invention

The present invention relates to amplifiers and, more particularly, a method of reducing the difference in amplitude between output signals.

2. Background of the Invention

There is usually a tight tolerance placed on the gain and phase of an amplifier; however gain and phase errors cause significant problems.

When a radio telecommunications base station for example needs to have its output power increased beyond its usual rating (e.g. to increase cell size), it is known for a parallel amplifier stage to be added to it, as shown in FIG. 1. The known parallel amplifier stage includes a splitter before and a combiner after the two (or more) amplifiers as shown in more detail in FIG. 2.

If all of the amplifiers in the parallel amplifier stage are ideal, that is exactly the same, then the combining and splitting process incurs no loss and the output power is doubled. In practice, the amplifiers are different. Even if built to very strict specifications, amplifiers differ, for example because they are different ages or from different suppliers.

The splitting and combining process occurring in the parallel amplifier stage is only lossless when the amplifiers are exactly the same. Even small differences cause significant losses to be incurred, and the RF output power will be lower than ideal multiplying-up of power, for example doubling of power when the parallel amplifier stage has two amplifiers. Dependent on the type of combining used any power that is lost is converted to heat in a dump port of the combiner connected to the amplifiers' output ports, or reflected back to the amplifiers and converted to heat in dump ports of each amplifier, namely in isolators at the amplifiers' outputs. As is known, some combiners are four port networks having two input ports, an output port and an isolated port (dump port) via which the power difference between input signals at any instant is output.

It will thus be seen that known approaches to the use of parallel amplifiers involve the use of dump port(s) acting as a large heatsink to dissipate wasted heat. The amplifiers have to be larger and more expensive in consequence to overcome this waste. In a base station, circuitry including amplifiers is one of the most expensive parts, and the cost in power amplifiers alone is considerable. Any way of reducing power wastage thereby reducing the need to generate excess power to compensate is significant.

### SUMMARY OF THE INVENTION

The present invention provides a circuit comprising at least two amplifiers electrically connected in parallel, including a controller operative to reduce the difference in amplitude between output signals from the amplifiers. The controller of the present invention also being operative to determine or receive an indicator of the difference in amplitude between the output signal of a first amplifier and the output signal of a second amplifier, and to adjust the gain of at least one of the first and second amplifiers dependent upon the indicator.

Advantageously, the controller may determine the indicator by sampling the output signal of a first amplifier and the output signal of a second amplifier and comparing the sample signals. Advantageously, the controller may receive the sample signals from respective directional couplers. Advantageously, the controller may receive the sample signals from the directional couplers, one of which provided at each input port to the combiner. Furthermore, directional couplers may be provided in a combiner assembly. Alternatively, the controller may receive the sample signals from the directional couplers, one of which is provided at the output port of each amplifier, and furthermore each directional coupler may be an amplifier assembly.

Alternatively, the indicator is a measure of power dissipated. The output ports of the amplifiers may be connected by a combiner having multiple input ports, an output port and a dump port, the indicator being determined by the controller by measuring power output to the dump port. Alternatively, at least one amplifier has a circulator/isolator, the indicator may be determined by the controller by detecting power dissipated in at least one of the circulator(s)/isolator(s). Each amplifier may have a circulator/isolator, the indicator being determined by the controller by combining the signals representative of power dissipated in each circulator/isolator.

Advantageously, the controller may also be operative to reduce the difference in phase between output signals from the amplifiers. Here, the controller may be operative to determine or receive a further indicator, the further indicator being indicative of the difference in phase between the output signal of a first amplifier and the output signal of a second amplifier, and to adjust the phase of the input signal to at least one of the amplifiers dependent upon the further indicator.

The present invention may also provide a radio telecommunications base station comprising the circuit. Furthermore the base station may be a Universal Mobile Telecommunications System base station.

The present invention may also provide a method of reducing the difference in amplitude between output signals from amplifiers electrically connected in parallel. by determining an indicator of the difference in amplitude between the output signal of a first amplifier and the output signal of a second amplifier, and adjusting the gain of at least one of the first and second amplifiers dependent upon the indicator.

The indicator may also be provided by sampling the output signal of a first amplifier and the output signal of a second amplifier and comparing the sample signals.

Alternatively, the indicator is a measure of power dissipated. Output ports of the amplifiers may be connected by a combiner having multiple input ports, an output port and a dump port, the indicator being determined by measuring power output to the dump port.

Alternatively, at least one amplifier may have a circulator/isolator, the indicator being determined by detecting power dissipated in at least one of the circulator(s)/isolator(s). Each amplifier may have a circulator/isolator, the indicator being determined by combining the signals representative of power dissipated in each circulator/isolator.

The difference in phase between the output signals from the amplifiers may also be undertaken by determining a further indicator. Here, the further indicator may be indicative of the difference in phase between the output signal of a first amplifier and the output signal of a second amplifier, and adjusting the phase of the input signal to at least one of the amplifiers in dependence on the further indicator.

Advantageous embodiments of the present invention may be considered as an intelligent RF power combiner. Advantageous embodiments may include that the power lost if combining two (or more) power amplifiers in parallel is reduced. The loss may be reduced at the combined output of the parallel amplifiers. This in turn reduces the d.c. power needed to generate this RF power (typically 10% efficient), the cooling requirements of the system are reduced and the overall cost significantly reduced. By reducing the loss in the RF output power by just 0.5 dB, for example, considerable savings can be made from the cost of a base station.

### BRIEF DESCRIPTION OF THE DRAWINGS

The present invention will be better understood from reading the following description of non-limiting embodiments, with reference to the attached drawings, wherein below:

FIG. 1 is a diagram illustrating a radio telecommunications base station;

FIG. 2 is a diagram illustrating a known parallel amplifier stage;

FIG. 3 is a diagram illustrating a parallel amplifier stage according to a first embodiment;

FIG. 4 is a diagram illustrating a parallel amplifier stage according to a second embodiment;

FIG. 5 is a diagram illustrating a parallel amplifier stage according to a third embodiment; and

FIG. 6 is a diagram illustrating a parallel amplifier stage according to a fourth embodiment of the invention.

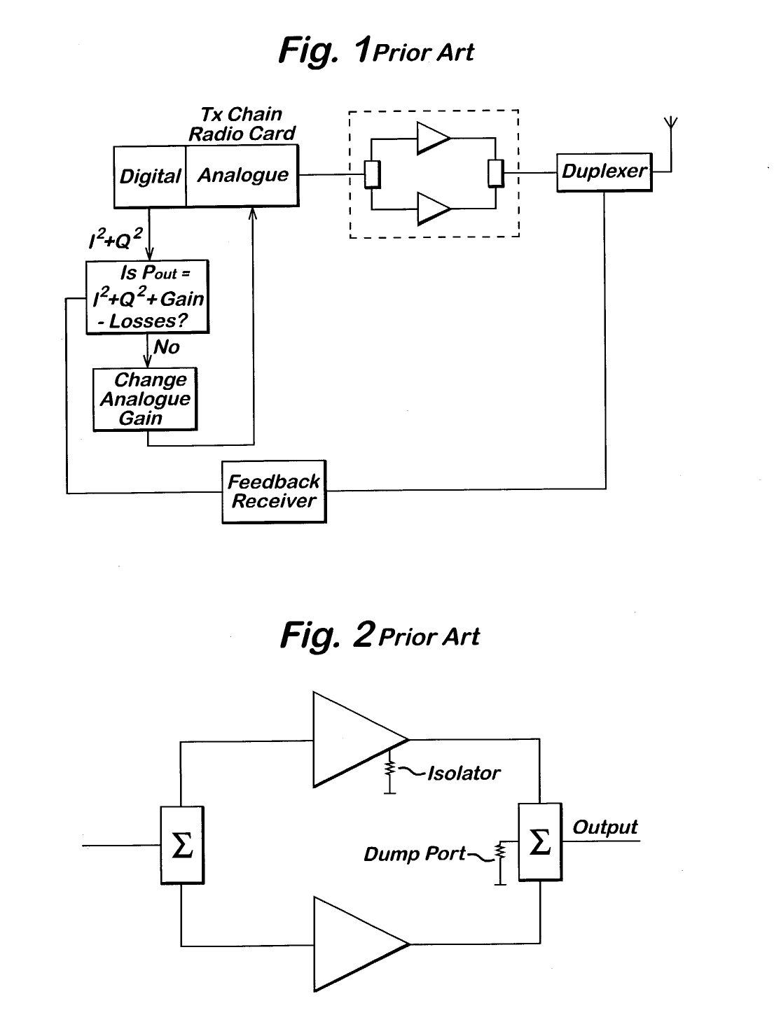

It should be emphasized that the drawings of the instant application are not to scale but are merely representations of the invention, which may be determined by one of skill in the art by examination of the information contained herein.

### DETAILED DESCRIPTION

Systems are described involving gain, or gain and phase, adjustment, to keep amplifiers well matched during operation. Basically by using feedback from the combining network it is possible to tightly control the amplifier characteristics and reduce the loss in the combiner.

It can be shown that if the two (or more) parallel amplifiers are gain and phase aligned then the combining process will be almost lossless. Of the two, gain alignment is most significant factor. Tightly controlling the phase as occurs in some embodiments brings relatively small improvements in the power loss but does help in maintaining linearization in amplifiers such as digital pre-distortion amplifiers and combined amplifiers.

There are various approaches to keeping the amplifier output signals aligned in gain (and optionally in phase also). These are considered below.

Measurement of the Difference in Magnitude in Each Path

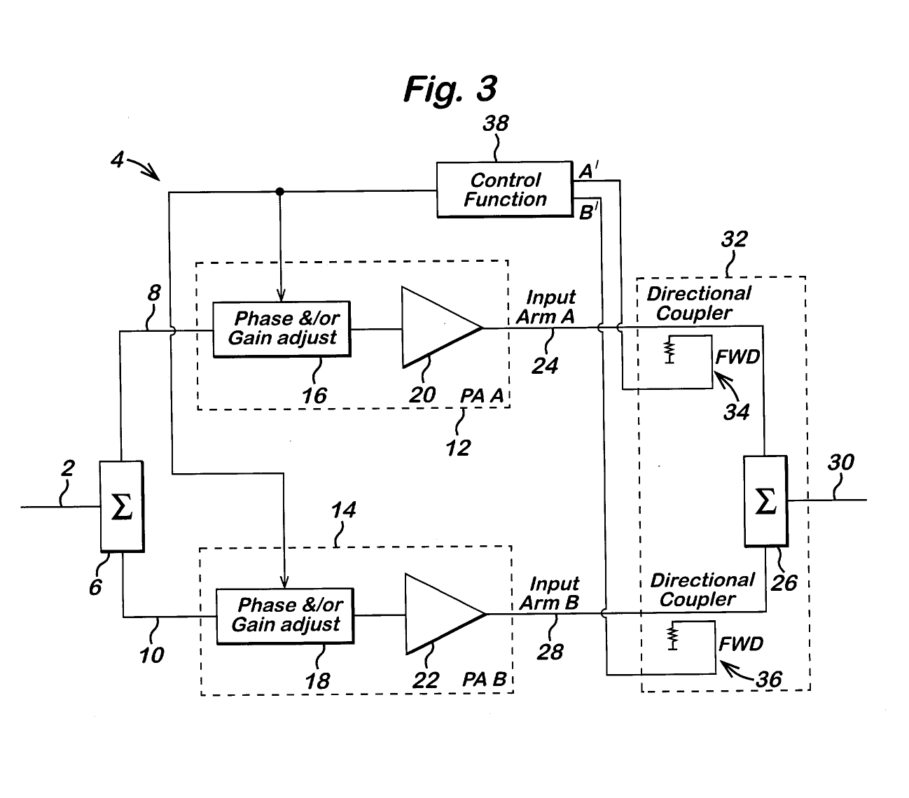

In the circuit configuration shown in FIG. 3, basically by measurement of the difference in magnitude in each path, a controller 38 alters the amplifier units 12,14 in order to achieve the minimum difference in gain, and hence the least power wasted due to losses in combiner 26 due to imbalances between signals A and B.

As shown in FIG. 3 the input 2 to the parallel amplifier stage 4, is connected to a splitter 6 having two outputs 8,10. The first output 8 is provided to a first power amplifier unit 12A and the second output 10 is provided to a second power amplifier unit 14, B. Each power amplifier unit 12,14 includes a phase and/or gain adjuster circuitry denoted 16, 18 respectively in addition to a power amplifier 20,22. The output from the first power amplifier unit 12 is provided on input arm A, 24 to a combiner 26 and the output from the second power amplifier unit 14 is provided on input arm B, 28 to a combiner 26. The combiner has an output 30.

The combiner 26 is part of a combiner unit 32 in which each input arm A, B that is arms 24,28 have an associated directional coupler denoted 34,36 respectively. The directional coupler 34 applied to arm A, 24 provides a relatively low power signal A′ proportional to the signal on arm A, 24. The directional coupler 36 applied to arm B, 28 provides a relatively low power signal B′ proportional to the signal on arm B, 28.

The two signals A′, B′ from the directional couplers 34,36 are provided to a controller 38 operative to compare the signals A′, B′ and send adjustment control signals to the power amplifier units 12,14. The controller 38 operates such that:

if A′=B′ send signal to do nothing to gain;

if A′<B′ send signal to increase gain of A relative to B; and

if A′>B′ send signal to increase gain of B relative to A.

In an alternative embodiment (not shown) difference in phase may also be monitored and the control function may operate to produce the minimum difference in phase.

Measurement of the Magnitude of the Output of Each Amplifier

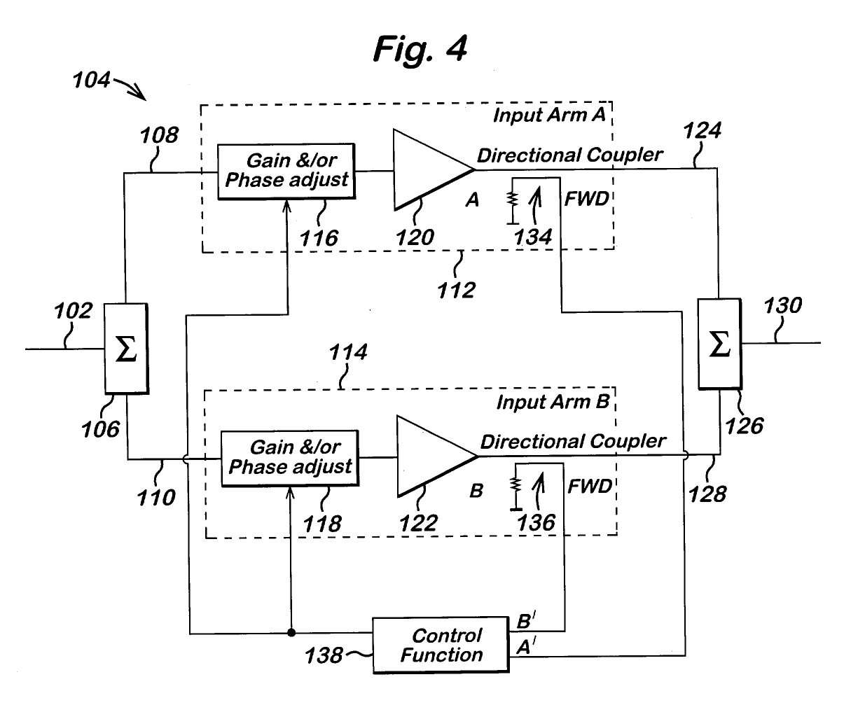

In the circuit configuration shown in FIG. 4, measurement of the magnitude of the output of each amplifier is undertaken before the combining network. This information is fed back to the gain adjustment mechanism within each amplifier. Using the measured information the amplifier tunes its gain to the required levels.

The circuit configuration shown in FIG. 4 is essentially the same as that shown in FIG. 3 except that the directional couplers are shifted from a combiner unit to within the amplifier units.

As shown in FIG. 4 the input 102 to the parallel amplifier stage 104, is connected to a splitter 106 having two outputs 108,110. The first output 108 is provided to a first power amplifier unit 112,A and the second output 110 is provided to a second power amplifier unit 114, B. Each power amplifier unit 112,114 includes a phase and/or gain adjuster circuitry denoted 116, 118 respectively in addition to a power amplifier 120,122. The output from the first power amplifier unit 112 is provided on input arm A, 124 to a combiner 126 and the output from the second power amplifier unit 114 is provided on input arm B, 128 to a combiner 126. The combiner has an output 130.

Within each amplifier unit 112, 114, each arm A, B that is arms 1.24,128 have an associated directional coupler denoted 134,136 respectively. The directional coupler 134 applied to arm A,124 provides a relatively low power signal A′ proportional to the signal on arm A, 24. The directional coupler 136 applied to arm B,128 provides a relatively low power signal B′ proportional to the signal on arm B, 128.

The two signals A′, B′ from the directional couplers 134,136 are provided to a controller 138 operative to compare the signals A′, B′ and send adjustment control signals to the power amplifier units 112,114. The controller 138 operates such that:

if A′=B′ do nothing to gain;

if A′<B′ send signal to increase gain of A relative to B; and

if A′>B′ send signal to increase gain of B relative to A.

In an alternative embodiment (not shown) phase of the output of each amplifier may also be measured for phase adjustment within each amplifier.

Monitoring of the Power Proportional to the Difference Between A and B

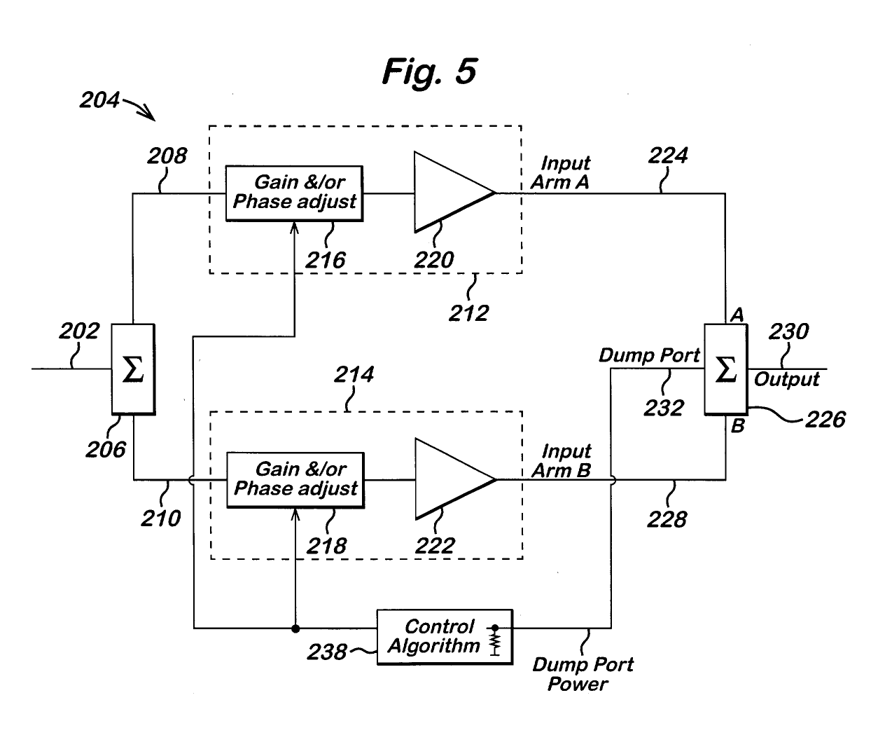

Using the configuration shown in FIG. 5, monitoring is undertaken of the power proportional to the difference between A and B dissipated in a dump port of a combiner 226. This can be done using a number of methods, including having a temperature monitor or an RF power monitor within a controller. Using a controller it is possible to alter the gain and phases of each amplifier to minimise the power lost in the dump port of the combiner.

The circuit configuration shown in FIG. 5 is essentially the same as that shown in FIGS. 3 and 4 except that rather than using directional couplers to sample amplified signals, a difference signal provided at a dump port of a combiner is used as a feedback signal instead.

As shown in FIG. 5 the input 202 to the parallel amplifier stage 204, is connected to a splitter 206 having two outputs 208,210. The first output 208 is provided to a first power amplifier unit 212,A and the second output 210 is provided to a second power amplifier unit 214, B. Each power amplifier unit 212,214 includes a phase and/or gain adjuster circuitry denoted 216, 218 respectively in addition to a power amplifier 220,222. The output from the first power amplifier unit 212 is provided on input arm A, 224 to a combiner 226 and the output from the second power amplifier unit 214 is provided on input arm B, 228 to the combiner 226. The combiner has an output 230.

The combiner 226 has an output port 230 and an isolated port (dump port 232) via which the power difference between signals on input arms A, B at any instant is output. The power difference signal is provided to a controller 238 operative to send adjustment control signals to the power amplifier units 212,214 dependent on the power difference signal so as to minimise the power difference.

In an advantageous embodiment, a temperature sensor (not shown) is provided in the controller 238 to provide a signal having an amplitude dependent on dump port power. In an alternative embodiment, an RF power meter is provided in the controller instead for the same purpose. In further alternative embodiments, a temperature sensor or power meter is provided in the combiner.

Monitor the Power Dissipated (Related to the Difference Between A and B)

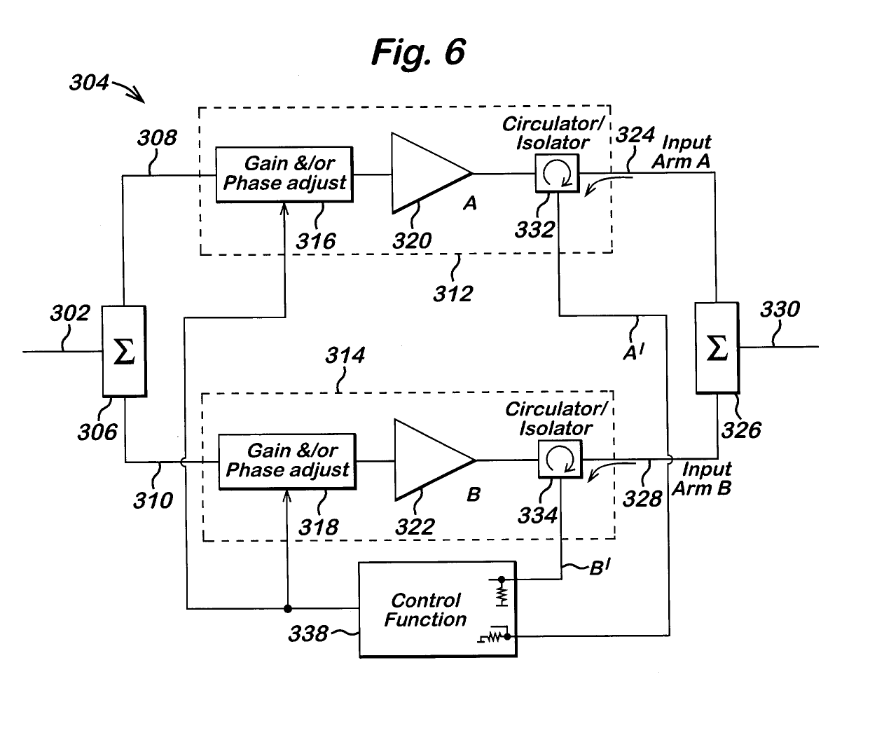

Using the configuration shown in FIG. 6, the power dissipated (related to the difference between A and B)in the isolator dump ports of each amplifier is monitored and a control algorithm is used in the controller to adjust the gain and phase of each amplifier to minimise dissipation. Reflected power due to impedance mismatches in the circuitry (mismatch uncertainty) mean this method is likely to be less accurate than the other methods proposed.

The circuit configuration shown in FIG. 6 is essentially the same as that shown in FIGS. 3 and 4 except that rather than using directional couplers to sample amplified signals, power dissipated at dump ports of the amplifiers is monitored to provide a feedback signal instead. The circuit configuration shown in FIG. 6 is essentially the same as that shown in FIG. 5 except that rather than using a dump port of a combiner, the amplifier units are each provided with a dump port (circulator/ isolator) from which a signal representative of respective power dissipation is taken.

As shown in FIG. 6 the input 302 to the parallel amplifier stage 304, is connected to a splitter 306 having two outputs 308,310. The first output 308 is provided to a first power amplifier unit 312,A and the second output 310 is provided to a second power amplifier unit 314, B. Each power amplifier unit 312,314 includes a phase and/or gain adjuster circuitry denoted 316, 318 respectively in addition to a power amplifier 320,322. The output from the first power amplifier unit 312 is provided on input arm A, 324 to a combiner 326 and the output from the second power amplifier unit 314 is provided on input arm B, 328 to the combiner 326. The combiner has an output 330 but does not have a dump port.

Each amplifier unit 312,314 includes a circulator/isolator 332,334 connected between its respective amplifier 320,322 and its respective output arm (input arm A, B to combiner 326). The two circulator/isolators 332,334 act as dump ports providing signals A′, B′ related to power reflected from combiner input ports 324, 328 due to power imbalance at the combiner 326. The signals A′,B′ are provided to a controller 338 operative to send adjustment control signals to the power amplifier units 212,214 dependent on the signals A′,B′ it receives, so as to reduce waste power dissipation.

While the particular invention has been described with reference to illustrative embodiments, this description is not meant to be construed in a limiting sense. It is understood that although the present invention has been described, various modifications of the illustrative embodiments, as well as additional embodiments of the invention, will be apparent to one of ordinary skill in the art upon reference to this description without departing from the spirit of the invention, as recited in the claims appended hereto. It is therefore contemplated that the appended claims will cover any such modifications or embodiments as fall within the true scope of the invention.

1. A circuit comprising a controller for reducing the difference in amplitude between output signals from at least two amplifiers, and for determining and/or receiving an indicator of the difference in amplitude between the output signal of a first amplifier and the output signal of a second amplifier, and for adjusting a gain of at least one of the amplifiers in response to the indicator.

2. The circuit of claim 1, wherein the controller determines the indicator by sampling the output signal of the first amplifier and the output signal of the second amplifier and comparing the sample signals.

3. The circuit of claim 2, wherein the controller receives the sample signals from respective directional couplers.

4. The circuit of claim 1, wherein the indicator is a measure of power dissipated.

5. The circuit of claim 4, wherein the output ports of the amplifiers are coupled by a combiner having multiple input ports, an output port and a dump port, the indicator being determined by the controller by measuring power output to the dump port.

6. The circuit of claim 4, wherein the at least one amplifier comprises at least one circulator and/or at least one isolator, and the indicator being determined by the controller detecting power dissipated in at least one of the circulators and/or at least one of the isolators.

7. The circuit of claim 6, wherein each amplifier comprises at least one circulator and/or at least one isolator, the indicator being determined by the controller combining the signals representative of power dissipated in each circulator and/or isolator.

8. The circuit of claim 1, wherein the controller reduces the difference in phase between output signals from the amplifiers, the controller determines and/or receives a further indicator indicative of the difference in phase between the output signal of the first amplifier and the output signal of the second amplifier, and the controller adjusts the phase of the input signal to at least one of the first and second amplifiers in response to the further indicator.

9. A radio telecommunications base station comprising the circuit according to claim 1.

10. A method of reducing the difference in amplitude between output signals from amplifiers coupled in parallel comprising:
determining an indicator of the difference in amplitude between the output signal of a first amplifier and the output signal of a second amplifier; and
adjusting the gain of at least one of the first and second amplifiers dependent upon the indicator.
